(19) United States
(12) Patent Application Publication
(10) Pub. No.: US 2024/0179871 A1
(43) Pub. Date: May 30, 2024

(54) VAPOR CHAMBER

(71) Applicant: COOLER MASTER CO., LTD., Taipei City (TW)

(72) Inventors: Hua-Yuan LIN, Taipei City (TW); Yao-Chun WANG, Taipei City (TW)

(73) Assignee: COOLER MASTER CO., LTD., Taipei City (TW)

(21) Appl. No.: 18/524,025

(22) Filed: Nov. 30, 2023

(30) Foreign Application Priority Data
Nov. 30, 2022 (TW) 111145949

(51) Int. Cl. H05K 7/20

(52) U.S. Cl. CPC H05K 7/20327

(57) ABSTRACT

A vapor chamber including a first plate, second plate, plurality of support structures, and plurality of heat transfer structures is provided. The first plate and the second plate define an interior cavity having a first portion, a pair of second portions, and a pair of third portions. The pair of second portions and pair of third portions surround the first portion. A length of the pair of third portions defines a longitudinal direction and is greater than a width of the pair of second portions. The plurality of heat transfer structures is disposed in the first portion and the plurality of support structures is disposed throughout the interior cavity. A position of the structure length of each of the plurality of heat transfer structures is in line with the longitudinal direction so that working fluid flows from the pair of third portions to and through the first portion unhindered.

### RELATED APPLICATIONS

This US application claims the benefit of priority to Chinese application No. 111145949, filed on Nov. 30, 2022, of which is incorporated herein by reference in its entirety.

### TECHNICAL FIELD

The present disclosure is related to the field of heat transfer in general and more particularly but not limited to vapor chambers.

### BACKGROUND OF THE INVENTION

With the increase of the processing speed and performance of electronic components, such as application-specific integrated circuits (ASICs) and central processing units (CPU), the amount of heat generated during the operation of the electronic component increases. The heat generation increases the temperature of the electronic component and, if the heat cannot be dissipated effectively, the reliability and performance of the electronic component are reduced.

To prevent overheating of an electronic component of a thin and compact electronic device, a vapor chamber may be used. The generated heat of the electronic component is conducted through a limited area of the electronic component to a larger area of the vapor chamber, and the generated heat can be unevenly and inefficiently distributed along the vapor chamber. Consequently, the vapor chamber may not adequately cool the electronic component, potentially causing the electronic component to overheat.

### SUMMARY OF THE INVENTION

Aspects of the disclosure provide a vapor chamber. The vapor chamber can include a first plate, a second plate opposite the first plate, the first plate and the second plate defining an interior cavity, the interior cavity comprising, a first portion, a pair of second portions, and a pair of third portions, the first portion surrounded by the pair of second portions and the pair of third portions, the pair of second portions on opposite sides of the first portion and the pair of third portions on opposite sides of the first portion different from the opposite sides of the pair of second portions, each pair of second portions having a width extending from a respective opposite side of the first portion to a respective perimeter interior side wall of the vapor chamber, each pair of third portions having a length extending from a respective opposite side of the first portion to a respective perimeter interior side wall of the vapor chamber, the length of each pair of third portions defining a longitudinal direction, the first portion having a first depth extending from the first plate to the second plate, each pair of second portions and each pair of third portions further having a second depth extending from the first plate to the second plate, a plurality of support structures disposed in the first portion, the pair of second portions, and the pair of third portions, respectively, each plurality of support structures having a first support contact end, and a second support contact end opposite to each other and a structure diameter, the first support contact ends contacts the second plate, and a plurality of heat transfer structures disposed in the first portion, each plurality of heat transfer structures having a first heat transfer contact end, and a second heat transfer contact end opposite to each other and a structure length, the first heat transfer contact ends contact the second plate, wherein the length of each pair of third portions is greater than the width of each pair of second portions, the first depth is greater than the second depth, and the structure length is greater than the structure diameter, and wherein a position of the structure length of each of the plurality of heat transfer structures is in line with the longitudinal direction.

In an embodiment, the vapor chamber can further include a centerline, the centerline passing through the first portion and each of the pair of third portions, the centerline intersecting a center of the vapor chamber, and wherein at least one of the plurality of heat transfer structures further has a maximum structure length, the maximum structure length is greater than the structure length, wherein a position of the maximum structure length is centered along the centerline.

In an embodiment, the vapor chamber can further include a working fluid disposed in the interior cavity, wherein the first portion further has a first volume, the pair of second portions further has a second volume, and the pair of third portions further has a third volume, and the first portion is configured to have the working fluid transitions between a liquid phase and a gas phase when heated, and the pair of second portions and the pair of third portions are configured to have the gas phase of the working fluid condenses back into a liquid phase when cooled, wherein the third volume is greater than the second volume, and the position of the structure length of each of the plurality of heat transfer structures is in line with the longitudinal direction to have the condensed working fluid flows from the pair of third portions to and through the first portion unhindered by any non-parallel plurality of heat transfer structures.

In an embodiment, the plurality of support structures have a cylinder shape.

In an embodiment, the vapor chamber can further include a heat source contact surface opposite the first portion, the heat source contact surface being configured to thermally couple to a heat source, wherein a total area of the second heat transfer contact ends for all of the plurality of heat transfer structures is greater than 12 percent, inclusive, of a total area of the heat source contact surface. In an embodiment, the plurality of heat transfer structures disposed in the first portion decrease a vapor space of the first portion, increasing a temperature within the first portion, and increasing a temperature difference between the temperature within the first portion and the temperature within the pair of second portions and between the temperature within the first portion and the temperature within the pair of third portions when the heat source contact surface is thermally coupled to the heat source.

In an embodiment, each of the plurality of heat transfer structures being spaced apart from each other and parallel to each other. In an embodiment, none of the plurality of support structures being disposed between each of the plurality of heat transfer structures. In an embodiment, at least one of the plurality of support structures being disposed between at least two of the plurality of heat transfer structures.

In an embodiment, the vapor chamber can further include a plurality of heat transfer base structures disposed in the first portion, each plurality of heat transfer base structures having a first heat transfer base contact end and a second heat transfer base contact end opposite to each other and a base structure length, the second heat transfer base contact ends contacts the first plate, at least one of the first heat transfer base contact ends contacts the second heat transfer contact ends and at least one of the first heat transfer base contact ends contacts at least one of the second support contact ends, wherein the base structure length is greater than the structure length and the structure diameter, and wherein a direction of the base structure length is the same as the longitudinal direction. In an embodiment, a total area of the second heat transfer contact ends for all of the plurality of heat transfer structures is between 30 percent and 70 percent, inclusive, of a total area of the first heat transfer base contact ends for all of the plurality of heat transfer base structures. In an embodiment, the plurality of heat transfer base structures and the plurality of heat transfer structures have a rectangular cuboid-like shape. In an embodiment, the vapor chamber can further include a wick structure disposed on an inner surface of the first plate, and outer surfaces of the plurality of support structures, the plurality of heat transfer structures, and the plurality of heat transfer base structures. In an embodiment, at least two of the plurality of heat transfer structures are disposed on one of the plurality of heat transfer base structures. In an embodiment, at least one of the plurality of support structures is disposed between the at least two of the plurality of heat transfer structures.

### BRIEF DESCRIPTION OF DRAWINGS

Unless specified otherwise, the accompanying drawings illustrate aspects of the innovative subject matter described herein. Referring to the drawings, wherein like reference numerals indicate similar parts throughout the several views, several examples of vapor chambers incorporating aspects of the presently disclosed principles are illustrated by way of example, and not by way of limitation.

FIG. 1 shows a perspective view of a vapor chamber according to one embodiment of the present disclosure.

FIG. 2A shows a perspective view of a first plate of the vapor chamber of FIG. 1 according to one embodiment of the present disclosure.

FIG. 2B shows an enlarged view of a first portion of an interior cavity of the vapor chamber of FIG. 1 according to one embodiment of the present disclosure.

FIG. 3 shows an enlarged view of a first portion of an interior cavity of a vapor chamber 10B according to one embodiment of the present disclosure.

FIG. 4 shows an enlarged view of a first portion of an interior cavity of a vapor chamber 10C according to one embodiment of the present disclosure.

FIG. 5 shows a cross-sectional view of the vapor chamber 10 of FIG. 1 without a wick structure 600 according to one embodiment of the present disclosure.

FIG. 6 shows a cross-sectional view of a vapor chamber 10D with a wick structure 600 according to one embodiment of the present disclosure.

### DETAILED DESCRIPTION

The following describes various principles related to thermal control of electronic components by way of reference to specific examples of vapor chambers, including specific arrangements and examples of interior cavity portions embodying innovative concepts. More particularly, but not exclusively, such innovative principles are described in relation to selected examples of plurality of heat transfer structures disposed in the interior cavity and how the plurality of heat transfer structures decrease a vapor space to evenly and efficiently distribute heat along the vapor chamber, increase a velocity of flow of working fluid that is condensed back into a liquid phase to a center of the vapor chamber, and allow the flow of working fluid to the center of the vapor chamber to travel unhindered, and well-known functions or constructions are not described in detail for purposes of succinctness and clarity. Nonetheless, one or more of the disclosed principles can be incorporated in various other embodiments of a plurality of heat transfer structures to achieve any of a variety of desired outcomes, characteristics, and/or performance criteria.

Thus, vapor chambers having attributes that are different from those specific examples discussed herein can embody one or more of the innovative principles, and can be used in applications not described herein in detail. Accordingly, embodiments of vapor chambers not described herein in detail also fall within the scope of this disclosure, as will be appreciated by those of ordinary skill in the relevant art following a review of this disclosure.

Example embodiments as disclosed herein are directed to vapor chambers, wherein a surface of the vapor chamber is thermally coupled to an electronic component, transporting heat away therefrom, and to working fluid inside of the vapor chamber. In response to receiving the heat, a portion of the working fluid transitions from a liquid phase to a gas phase. The gas portion of the working fluid rises and distributes the received heat substantially evenly along the second plate of the vapor chamber. The second plate transfers the heat to ambient air outside of the vapor chamber. The working fluid condenses back into a liquid in response to conducting the heat to the second plate and the liquid returns to a center of the vapor chamber where the cycle is repeated.

The vapor chambers may be configured within an electric or electronics system that includes heat producing electronic components to be cooled.

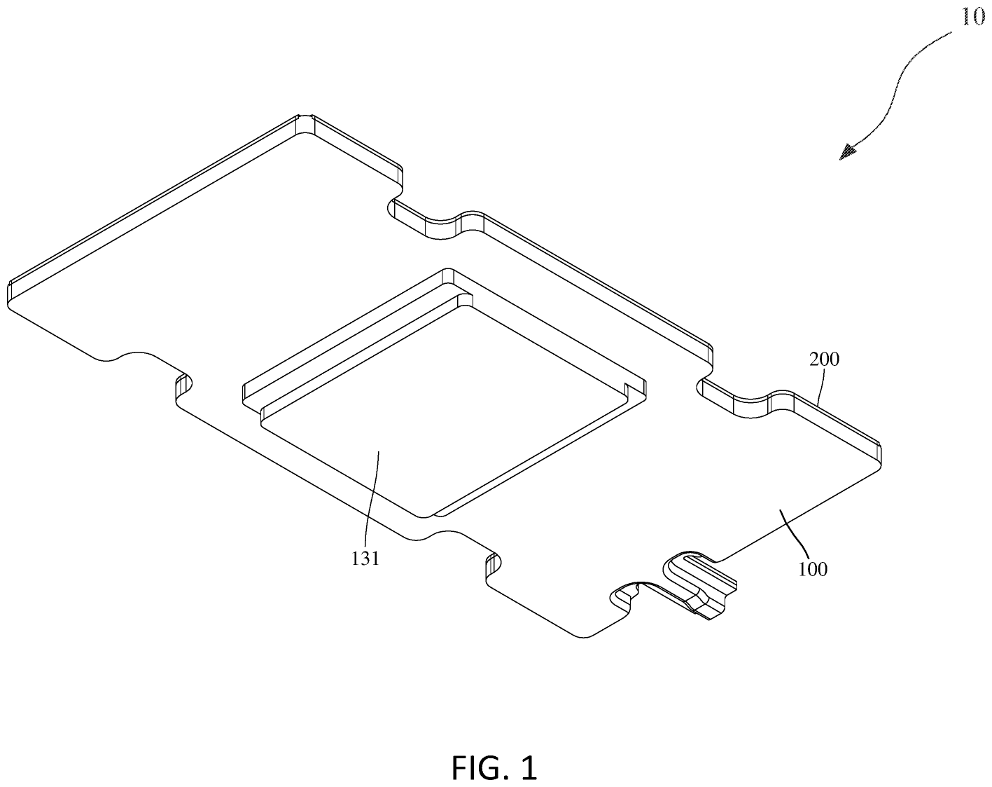

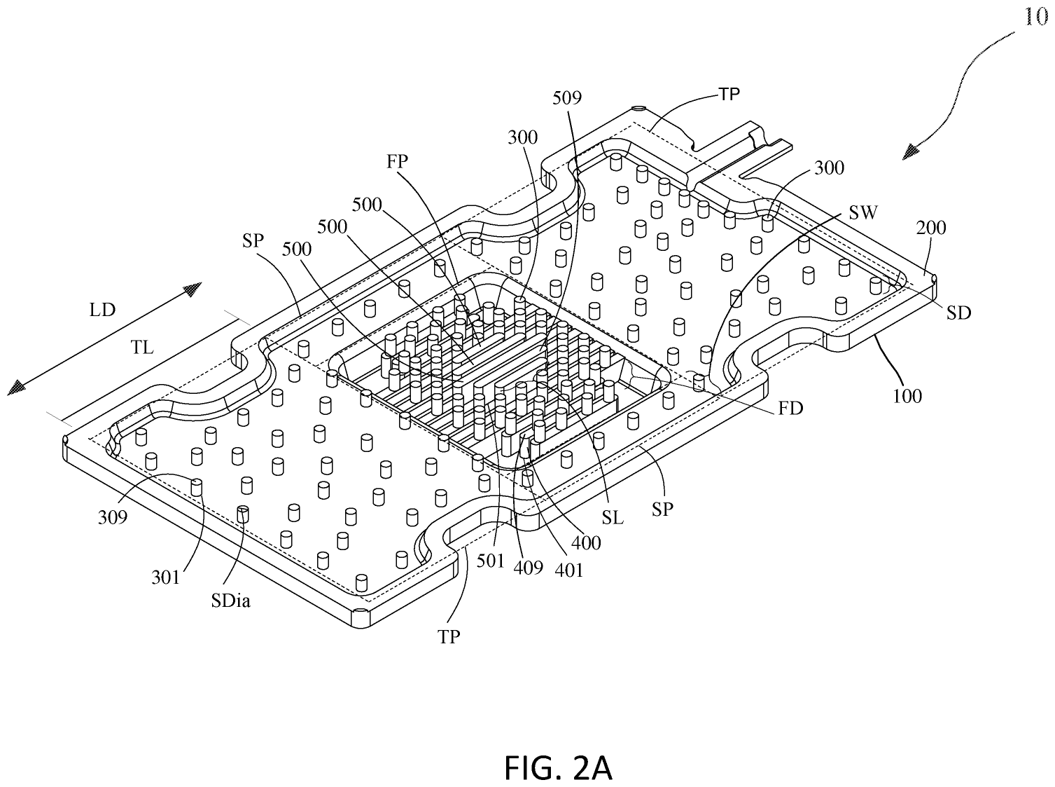

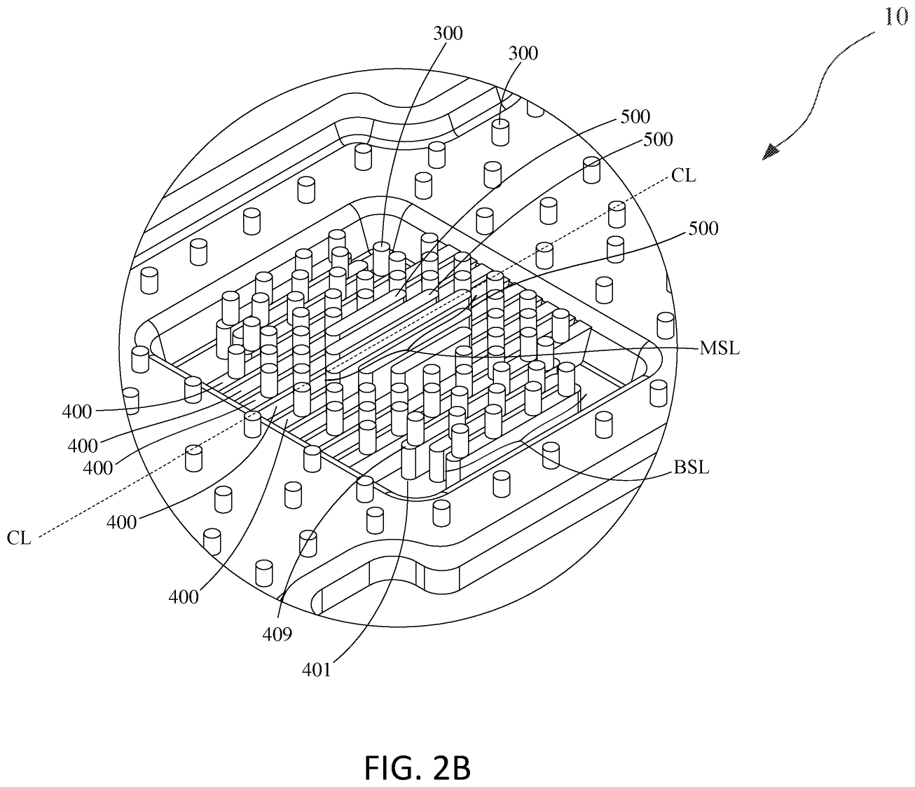

FIGS. 1, 2A and 2B show a vapor chamber 10 according to aspects of the present disclosure in different perspective views. The vapor chamber 10 includes a first plate 100, a second plate 200, a plurality of support structures 300, and a plurality of heat transfer structures 500. The second plate 200 is opposite to the first plate 100. The first plate 100 and the second plate 200 define an interior cavity FP/SP/TP. The interior cavity FP/SP/TP includes a first portion FP, a pair of second portions SP, and a pair of third portions TP. The first portion FP is surrounded by the pair of second portions SP and the pair of third portions TP. The pair of second portions SP is on opposite sides of the first portion FP and the pair of third portions TP is on opposite sides of the first portion FP different from the opposite sides of the pair of second portions SP. Each pair of second portions SP has a width SW extending from a respective opposite side of the first portion FP to a respective perimeter interior side wall of the vapor chamber 10. Each pair of third portions TP has a length TL extending from a respective opposite side of the first portion FP to a respective perimeter interior side wall of the vapor chamber 10. The length TL defines a longitudinal direction LD.

The first portion FP has a first depth FD extending from the first plate 100 to the second plate 200. Each pair of second portions SP and each pair of third portions TP further have a second depth SD extending from the first plate 100 to the second plate 200. The plurality of support structures 300 is disposed in the first portion FP, the pair of second portions SP, and the pair of third portions TP, respectively. Each plurality of support structures 300 has a first support contact end 309 and a second support contact end 301 opposite to each other and a structure diameter SDia. The first support contact ends 309 contacts the second plate 200. The plurality of heat transfer structures 500 are disposed in the first portion FP. Each plurality of heat transfer structures 500 has a first heat transfer contact end 509 and a second heat transfer contact end 501 opposite to each other and a structure length SL. The first heat transfer contact ends 509 can contact the second plate 200. The length TL is greater than the width SW, the first depth FD is greater than the second depth SD, and the structure length SL is greater than the structure diameter SDia. A position of the structure length SL of each of the plurality of heat transfer structures 500 is in line with the longitudinal direction LD.

In at least one embodiment, each of the second plate 200 and the first plate 100 include a substantially flat perimeter ledge surface and the second plate 200 is bonded to the first plate 100 via each of the substantially flat perimeter ledge surfaces to define the interior cavity FP/SP/TP. In at least one embodiment, a profile shape of the vapor chambers 10 can be a rectangular-like shape, whereby a profile shape of the first portion can be a square-like shape, a profile shape of each pair of second portions can be an elongated rectangle-like shape, and a profile shape of each pair of third portions can be a square-like shape.

Refer to FIG. 2B, in at least one embodiment, the vapor chamber 10 can further include a centerline CL. The centerline CL passes through the first portion FP and each of the pair of third portions TP and intersects the center of the vapor chamber 10. At least one of the plurality of heat transfer structures 500 further has a maximum structure length MSL. The length of the maximum structure length MSL is greater than The length of the structure length SL, and the position of the maximum structure length MSL is centered along the centerline CL.

In at least one embodiment, the vapor chamber 10 can further include a working fluid (not shown) and the first portion FP can further have a first volume, the pair of second portions SP can further have a second volume, and the pair of third portions TP can further have a third volume. The working fluid is disposed in the interior cavity FP/SP/TP. The first portion FP is configured so that the working fluid transitions between a liquid phase and a gas phase when heated. The pair of second portions SP and the pair of third portions TP are configured so that the gas phase of the working fluid condenses back into a liquid phase when cooled. The third volume is greater than the second volume, and the position of the structure length SL of each of the plurality of heat transfer structures 500 is in line with the longitudinal direction LD so that the condensed working fluid flows from the pair of third portions TP to and through the first portion FP unhindered by any non-parallel plurality of heat transfer structures 500.

In at least one embodiment, for the condensed working fluid to flow to and through the first portion FP, the position of the structure length SL of each of the plurality of heat transfer structures 500 can be in line with the longitudinal direction LD or not in line with the longitudinal direction LD, as an example, perpendicular or radial to the longitudinal direction LD.

Refer back to FIG. 2A, in at least one embodiment, the vapor chamber 10 can further include a plurality of heat transfer base structures 400. The plurality of heat transfer base structures 400 is disposed in the first portion FP. Each plurality of heat transfer base structures 400 has a first heat transfer base contact end 409 and a second heat transfer base contact end 401 opposite to each other and a base structure length BSL. The second heat transfer base contact ends 401 can contact the first plate 100.

In at least one embodiment, at least one of the heat transfer base structures 400 can contact at least one of the heat transfer structures 500. For example, as shown in FIG. 2A, the first heat transfer base contact end 409 of the heat transfer base structure 400 can contact the second heat transfer contact end 501 of the heat transfer structure 500. In at least one embodiment, at least one of the heat transfer base structures 400 can contact at least one of the support structures 300. For example, as shown in FIG. 2A, the first heat transfer base contact end 409 of the heat transfer base structure 400 can contact the second support contact end 301 of the support structure 300. The base structure length BSL is greater than the structure length SL and the structure diameter SDia. The direction of the base structure length BSL is the same as the longitudinal direction LD. In at least one embodiment, the base structure length BSL is equal to or less than the structure length SL.

The plurality of support structures 300 can have a cylinder shape. The plurality of heat transfer base structures 400 and the plurality of heat transfer structures 500 can have a rectangular cuboid-like shape. However, other shapes can also be used to form the support structure 300, the heat transfer base structure 400, and the heat transfer structure 500 according to the desired structure in an embodiment.

In at least one embodiment, a height of the plurality of support structures 300 is dependent on the second depth SD extending from the first plate 100 to the second plate 200, and a height of the plurality of heat transfer base structures 400 and the plurality of support structures 300 and/or the plurality of heat transfer structures 500 is dependent on the first depth FD extending from the first plate 100 to the second plate 200.

In at least one embodiment, the vapor chamber 10 can further include a heat source contact surface 131 opposite the first portion FP as shown in FIG. 1. The heat source contact surface 131 is configured to thermally couple to a heat source (not shown). The total area of the second heat transfer contact ends 509 for all of the plurality of heat transfer structures 500 is greater than 12 percent, inclusive, of the total area of the heat source contact surface 131. In at least one embodiment, the plurality of heat transfer structures 500 disposed in the first portion FP can decrease a vapor space of the first portion FP, increasing the temperature within the first portion FP, and increasing the temperature difference between the temperature within the first portion FP and the temperature within the pair of second portions SP and between the temperature within the first portion FP and the temperature within the pair of third portions TP when the heat source contact surface 131 is thermally coupled to the heat source.

In at least one embodiment, each of the plurality of heat transfer structures 500 is spaced apart from each other and parallel to each other. In at least one embodiment, none of the plurality of support structures 300 is disposed between each of the plurality of heat transfer structures 500. In at least one embodiment, the amount of the plurality of heat transfer structures 500 can be five as shown in FIG. 2A, and a perimeter profile of the plurality of heat transfer structures 500 can form an oval-like shape.

In at least one embodiment, the total area of the first heat transfer contact ends 509 for all of the plurality of heat transfer structures 500 is between 30 percent and 70 percent, inclusive, of the total area of the first heat transfer base contact ends 409 for all of the plurality of heat transfer base structures 400.

In at least one embodiment, the plurality of support structures 300 can be integrally formed in the second portion SP and third portion TP, respectively. The plurality of heat transfer base structures 400 can be integrally formed in the first portion FP. The plurality of support structures 300 disposed on the plurality of heat transfer base structures 400 and the plurality of heat transfer structures 500 disposed on the plurality of heat transfer base structures 400 can be integrally formed together, respectively, in the first portion FP. In at least one embodiment, the material of the plurality of heat transfer structures 500, the plurality of heat transfer base structures 400, and the first plate 100 can be, for example, copper. In at least one embodiment, the plurality of support structures 300 and the plurality of heat transfer structures 500 can be welded to the second plate 200. The copper material of the first plate 100, the plurality of heat transfer base structures 400, and the plurality of heat transfer structures 500, can decrease the temperature difference between the contact portions with the first plate 100 and the contact portions of the second plate 200, which can improve the heat flux through the vapor chambers 10.

When a heat source generates condensed heat in a small area, the vapor chamber 10 may experience dry-out at the location connected to the small area of the heat source. The copper material of the connected heat transfer structures 500 and the heat transfer base structures 400 can be used to help thermally transfer the heat away from the heat source and reduce the dry-out of the vapor chamber 10 at the small area. The connected heat transfer structures 500 and the heat transfer base structures 400 can also provide mechanical strength to the vapor chamber 10.

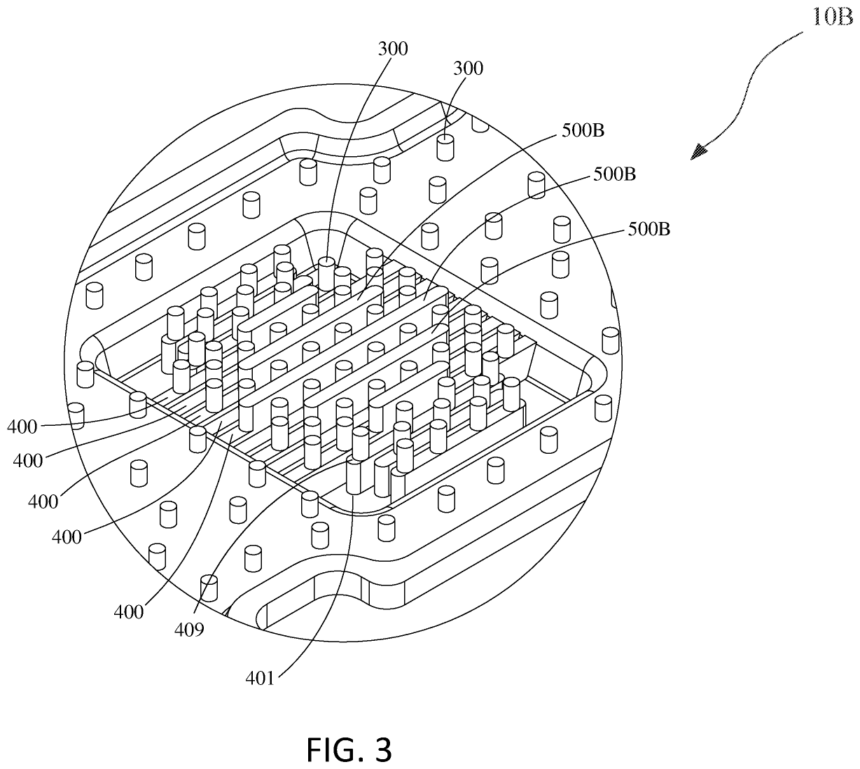

FIG. 3 shows an enlarged view of a first portion FP of an interior cavity of another vapor chamber 10B according to one embodiment of the present disclosure. The vapor chamber 10B of FIG. 3 may be similar in some respects to the vapor chamber 10 of FIGS. 1, 2A, and 2B, and therefore may be best understood with reference thereto where like numerals designate like components not described again in detail. In at least one embodiment, at least one of the plurality of support structures 300 is disposed between at least two of the plurality of heat transfer structures 500B (similar to the plurality of heat transfer structures 500 in FIG. 1, 2A-B). In at least one embodiment, the amount of the plurality of heat transfer structures 500B can be five, and rows of support structures 300, separated by a distance, can be disposed between each of the plurality of heat transfer structures 500B, wherein a perimeter profile of the plurality of heat transfer structures 500B can form a circle-like shape.

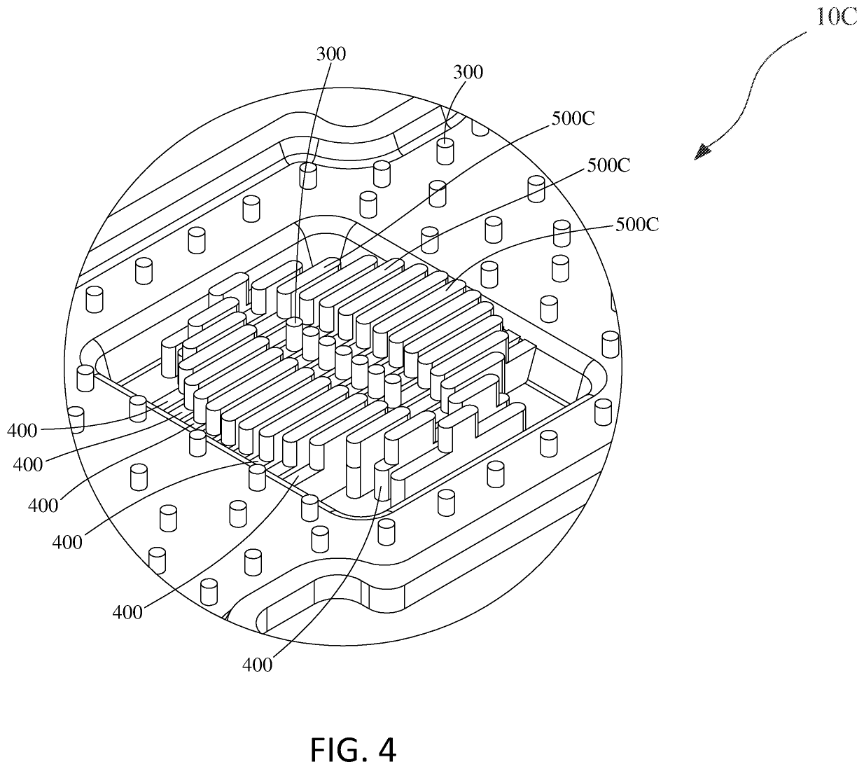

FIG. 4 shows an enlarged view of a first portion of an interior cavity of another vapor chamber 10C according to one embodiment of the present disclosure. The vapor chamber 10C of FIG. 4 may be similar in some respects to the vapor chamber 10 of FIGS. 1, 2A and 2B, and therefore may be best understood with reference thereto where like numerals designate like components not described again in detail. In at least one embodiment, at least two of the plurality of heat transfer structures 500C (similar to the plurality of heat transfer structures 500 in FIG. 1, 2A-B) is disposed on one of the plurality of heat transfer base structures 400. In at least one embodiment, at least one of the plurality of support structures 300 is disposed between the at least two of the plurality of heat transfer structures 500C and disposed on one of the plurality of heat transfer base structures 400. In at least one embodiment, the amount of the plurality of heat transfer structures 500C can be twenty eight, whereby two of the plurality of heat transfer structures 500C can be disposed on thirteen of the plurality of heat transfer base structures 400, and one row of support structures 300, separated by a distance, can be disposed between seven of the at least two of the plurality of heat transfer structures 500C, wherein a perimeter profile of the plurality of heat transfer structures 500C can form a circle-like shape.

In at least one embodiment, an amount of the plurality of heat transfer structures 500, 500B, 500C and an amount of the plurality of heat transfer base structures 400 can be one each.

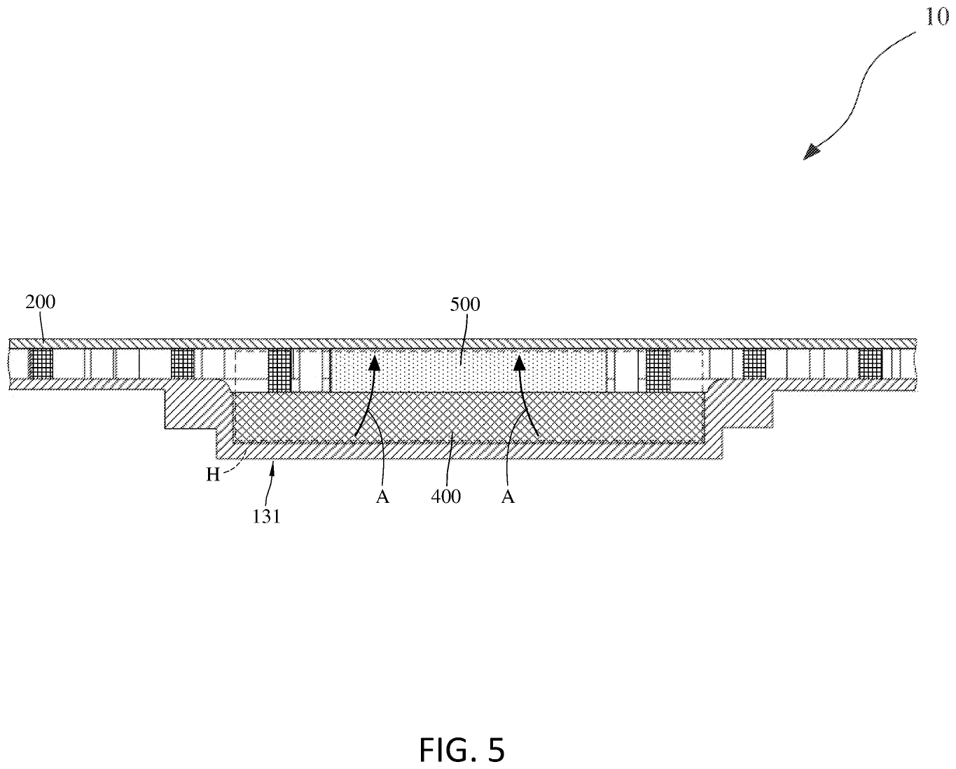

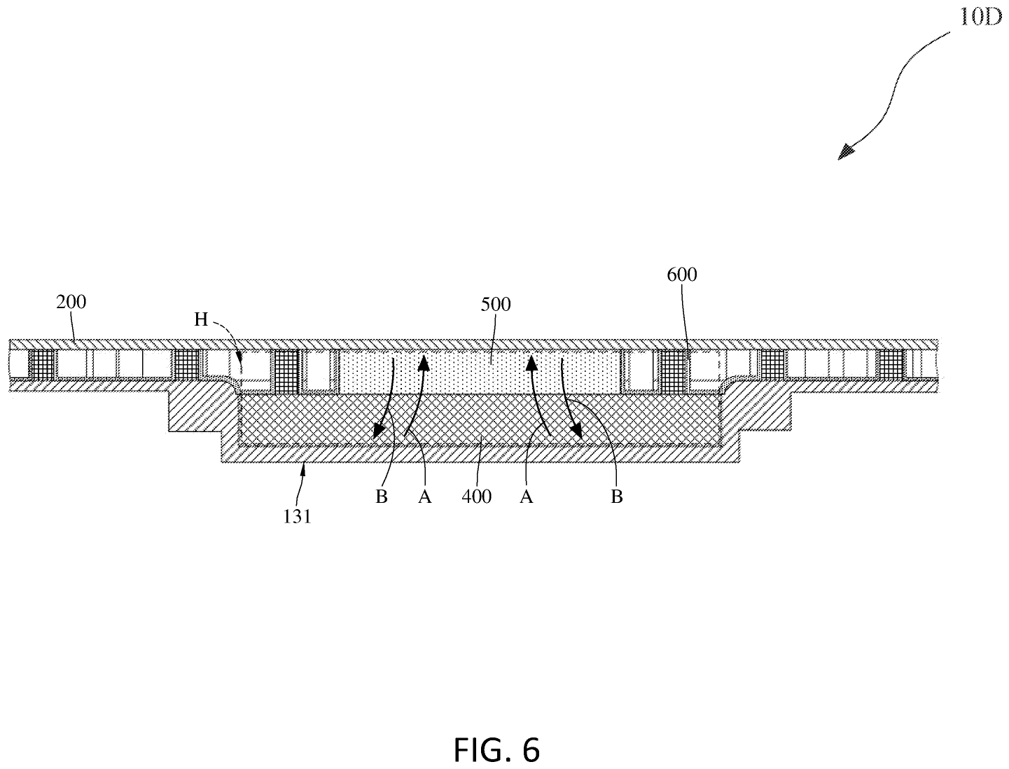

FIG. 5 shows a cross-sectional view of the vapor chamber 10 of FIG. 1 without a wick structure 600 according to one embodiment of the present disclosure. The cross-section cuts through the vapor chamber 10 along the centerline CL as shown in FIG. 2B. FIG. 6 shows a cross-sectional view of another vapor chamber 10D with a wick structure 600 according to one embodiment of the present disclosure. The cross-section cuts through the vapor chamber 10D along a centerline CL similar to the centerline CL as shown in FIG. 2B. The vapor chamber 10D of FIG. 6 may be similar in some respects to the vapor chamber 10 of FIGS. 1, 2A, 2B, and 5 and therefore may be best understood with reference thereto where like numerals designate like components not described again in detail. Evaporation region H is within the first portion FP of the interior cavity and is where the working fluid changes from liquid to vapor. The vapor chamber 10D can further include a wick structure 600 disposed on an inner surface of the first plate 100. The vapor chamber 10D can further include a wick structure 600 disposed on outer surfaces of the plurality of support structures 300, the plurality of heat transfer structures 500, and the plurality of heat transfer base structures 400. The wick structure 600 provides capillary pressure for the phase change (liquid-vapor-liquid) mechanism A, B of the vapor chamber 10D and acts as a channel for working fluid reflux. The wick structure 600 disposed on the plurality of heat transfer structures 500 and the plurality of heat transfer base structures 400 can increase the evaporation area of the working fluid. In at least one embodiment, the wick structure 600 disposed on the plurality of heat transfer base structures 400 where the plurality of heat transfer base structures 400 connects the sidewalls of the cavity defined by the first portion FP can increase the channel for working fluid reflux. In at least one embodiment, the wick structure is made of at least one of a metal mesh, sintered metal powder, sintered ceramic powder, or any combination of the foregoing.

The vapor chambers 10, 10B, 10C, and 10D of the present disclosure can evenly and efficiently distribute heat along the vapor chambers 10, 10B, 10C, and 10D. Consequently, the effectiveness of the vapor chambers 10, 10B, 10C, and 10D in dissipating heat via the phase change (liquid-vapor-liquid) mechanism is improved, increasing the thermal performance of the vapor chambers 10, 10B, 10C, and 10D. The length TL of the pair of third portions TP on opposite sides of the first portion FP, being greater than the width SW of the pair of second portions SP, expands the surface area, longitudinally, for working fluid to condense back into the liquid phase. Thus, a dimension of the vapor chambers 10, 10B, 10C, and 10D is smaller than if the width SW was equal to the length TL, decreasing a footprint within an electronics device, as an example, when the vapor chambers 10, 10B, 10C, and 10D are thermally coupled to the heat source.

The plurality of heat transfer structures 500 disposed in the first portion FP decrease a vapor space of the first portion FP, increasing the temperature within the first portion FP, and increasing the temperature difference between the temperature within the first portion FP and the temperature within the pair of second portions SP and between the temperature within the first portion FP and the temperature within the pair of third portions TP. Thus, heat along the pair of third portions TP is more evenly distributed and a velocity of flow of working fluid condensed back into a liquid phase from the pair of second portions SP and the pair of third portions TP of the interior cavity FP/SP/TP to the first portion FP of the interior cavity FP/SP/TP is increased.

Furthermore, working fluid condensed back into the liquid phase flowing from the pair of third portions TP to and through the first portion FP is unhindered by any non-parallel plurality of heat transfer structures 500 or non-parallel plurality of heat transfer base structures 400 via the positions of the structure length SL of each of the plurality of heat transfer structures 500 and the base structure length BSL of each of the plurality of heat transfer base structures 400 being in line with the longitudinal direction LD. Thus, the effectiveness of the vapor chambers 10, 10B, 10C, and 10D to dissipate heat via the phase change (liquid-vapor-liquid) mechanism is improved and the thermal performance of the vapor chambers 10, 10B, 10C, and 10D is increased.

A total area of the first heat transfer contact ends 509 for all of the plurality of heat transfer structures 500 is greater than 12 percent of a total area of the heat source contact surface 131. Thus, the total area of the first heat transfer contact ends 509 for all of the plurality of heat transfer structures 500 in contact with the second plate 200 is increased. As a result, an allowable compressive force of the vapor chambers 10, 10B, 10C, and 10D to the heat sources before the vapor chambers 10, 10B, 10C, and 10D collapse is increased via the plurality of heat transfer structures 500.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces.

What is claimed is:

1. A vapor chamber, comprising:
a first plate;
a second plate opposite the first plate, the first plate and the second plate defining an interior cavity, the interior cavity comprising, a first portion, a pair of second portions, and a pair of third portions, the first portion surrounded by the pair of second portions and the pair of third portions, the pair of second portions on opposite sides of the first portion and the pair of third portions on opposite sides of the first portion different from the opposite sides of the pair of second portions, each pair of second portions having a width extending from a respective opposite side of the first portion to a respective perimeter interior side wall of the vapor chamber, each pair of third portions having a length extending from a respective opposite side of the first portion to a respective perimeter interior side wall of the vapor chamber, the length of each pair of third portions defining a longitudinal direction, the first portion having a first depth extending from the first plate to the second plate, each pair of second portions and each pair of third portions further having a second depth extending from the first plate to the second plate;
a plurality of support structures disposed in the first portion, the pair of second portions, and the pair of third portions, respectively, each plurality of support structures having a first support contact end, and a second support contact end opposite to each other and a structure diameter, the first support contact ends contacts the second plate; and
a plurality of heat transfer structures disposed in the first portion, each plurality of heat transfer structures having a first heat transfer contact end, and a second heat transfer contact end opposite to each other and a structure length, the first heat transfer contact ends contact the second plate;
wherein the length of each pair of third portions is greater than the width of each pair of second portions, the first depth is greater than the second depth, and the structure length is greater than the structure diameter; and
wherein a position of the structure length of each of the plurality of heat transfer structures is in line with the longitudinal direction.

2. The vapor chamber of claim 1, further comprising a centerline, the centerline passing through the first portion and each of the pair of third portions, the centerline intersecting a center of the vapor chamber, and wherein at least one of the plurality of heat transfer structures further has a maximum structure length, the maximum structure length is greater than the structure length, wherein a position of the maximum structure length is centered along the centerline.

3. The vapor chamber of claim 1, further comprising a working fluid disposed in the interior cavity, wherein the first portion further has a first volume, the pair of second portions further has a second volume, and the pair of third portions further has a third volume, and the first portion is configured to have the working fluid transitions between a liquid phase and a gas phase when heated, and the pair of second portions and the pair of third portions are configured to have the gas phase of the working fluid condenses back into a liquid phase when cooled, wherein the third volume is greater than the second volume, and the position of the structure length of each of the plurality of heat transfer structures is in line with the longitudinal direction to have the condensed working fluid flows from the pair of third portions to and through the first portion unhindered by any non-parallel plurality of heat transfer structures.

4. The vapor chamber of claim 1, wherein the plurality of support structures have a cylinder shape.

5. The vapor chamber of claim 1, further comprising a heat source contact surface opposite the first portion, the heat source contact surface being configured to thermally couple to a heat source, wherein a total area of the second heat transfer contact ends for all of the plurality of heat transfer structures is greater than 12 percent, inclusive, of a total area of the heat source contact surface.

6. The vapor chamber of claim 5, wherein the plurality of heat transfer structures disposed in the first portion decrease a vapor space of the first portion, increasing a temperature within the first portion, and increasing a temperature difference between the temperature within the first portion and the temperature within the pair of second portions and between the temperature within the first portion and the temperature within the pair of third portions when the heat source contact surface is thermally coupled to the heat source.

7. The vapor chamber of claim 1, wherein each of the plurality of heat transfer structures being spaced apart from each other and parallel to each other.

8. The vapor chamber of claim 7, wherein none of the plurality of support structures being disposed between each of the plurality of heat transfer structures.

9. The vapor chamber of claim 7, wherein at least one of the plurality of support structures being disposed between at least two of the plurality of heat transfer structures.

10. The vapor chamber of claim 1, further comprising a plurality of heat transfer base structures disposed in the first portion, each plurality of heat transfer base structures having a first heat transfer base contact end and a second heat transfer base contact end opposite to each other and a base structure length, the second heat transfer base contact ends contacts the first plate, at least one of the first heat transfer base contact ends contacts the second heat transfer contact ends and at least one of the first heat transfer base contact ends contacts at least one of the second support contact ends, wherein the base structure length is greater than the structure length and the structure diameter, and wherein a direction of the base structure length is the same as the longitudinal direction.

11. The vapor chamber of claim 10, wherein a total area of the second heat transfer contact ends for all of the plurality of heat transfer structures is between 30 percent and 70 percent, inclusive, of a total area of the first heat transfer base contact ends for all of the plurality of heat transfer base structures.

12. The vapor chamber of claim 10, wherein the plurality of heat transfer base structures and the plurality of heat transfer structures have a rectangular cuboid-like shape.

13. The vapor chamber of claim 10, further comprising a wick structure disposed on an inner surface of the first plate, and outer surfaces of the plurality of support structures, the plurality of heat transfer structures, and the plurality of heat transfer base structures.

14. The vapor chamber of claim 10, wherein at least two of the plurality of heat transfer structures are disposed on one of the plurality of heat transfer base structures.

15. The vapor chamber of claim 14, wherein at least one of the plurality of support structures is disposed between the at least two of the plurality of heat transfer structures.
